(19) United States
(12) Patent Application Publication
(10) Pub. No.: US 2011/0005576 A1
(43) Pub. Date: Jan. 13, 2011

(54) PERSONAL SOLAR APPLIANCE

(76) Inventors: Melvin James Bullen, Los Gatos, CA (US); Bruno Richet, Albany, CA (US)

Correspondence Address: HAYNES AND BOONE, LLP;IP Section, 2323 Victory Avenue, Suite 700, Dallas, TX, 75219, US

(21) Appl. No.: 12/833,867

(22) Filed: Jul. 9, 2010

Related U.S. Application Data
(60) Provisional application No. 61/224,835, filed on Jul. 10, 2009.
(60) Provisional application No. 61/357,929, filed on Jun. 23, 2010.

(51) Int. Cl. H01L 31/052; H01L 31/048; H01L 31/18

(52) U.S. Cl. 136/246; 29/890.033

(57) ABSTRACT

A personal solar appliance (PSA) is presented that collects and stores solar energy. The PSA may be resilient enough to suffer all the knocks of extended human use and to have extensive exposure to the elements. Further, the PSA may be waterproof and provide thermal cooling. As such, some embodiments of the PSA includes a base with ventilation holes; a heat sink coupled to the base; a solar cell mounted to the heat sink opposite the base; a printed circuit board mounted to the heat sink opposite the solar cell; and a battery mounted to the base.

### RELATED APPLICATIONS

The current application claims priority to U.S. Provisional Application 61/224,835, filed on Jul. 10, 2009, and to U.S. Provisional Application 61/357,929, filed on Jun. 23, 2010, both of which are herein incorporated by reference in their entirety.

### BACKGROUND

1. Field

The present invention is related to solar energy generation and storage and, in particular, to a personal solar appliance for generation and storage of solar energy.

2. Discussion of Related Art

Solar cells or photovoltaic cells can be considered large area semiconductor diodes that convert sunlight into electrical current, which is used to produce usable power. The output power of the solar cell depends on multiple factors such as sunlight intensity, temperature, orientation of the cells with respect to the sun, and efficiency of the solar cells.

Photovoltaic systems, using solar panels, directly convert sunlight into energy using the principles of the photoelectric effect. The photoelectric effect takes advantage of the properties of semiconductor materials, with silicon being the primary material used in photovoltaic solar cells. When photons strike the solar cell, electrons in the semiconductor material are freed and allowed to flow as electricity. The direct current (DC) electricity produced can be directly used to charge batteries. The DC current can also be coupled to an inverter to power alternating current (AC) components or the AC current be connected to a local electrical power grid.

Traditional photovoltaic systems are based on silicon. Silicon ingots are sliced into wafers that are fabricated into cells. Cells are combined into modules, which are packaged into end-user systems. Silicon-based solar cells typically have efficiencies up to about 18%. Semiconductor materials, like gallium arsenide, have efficiencies that approach 40%, but are much higher costs than silicon. Gallium arsenide, therefore, is not currently economically practical for many terrestrial applications and is used for the most part on spacecraft and interplanetary robots. Thin film technologies use a variety of semiconductors but their efficiency is typically less than 10%.

A battery charger is a device used to put energy into a rechargeable battery by forcing an electric current into the battery. The charge current for a battery depends upon the technology and capacity of the battery being charged. For example, the current that should be applied to recharge a 12 volt car battery (several Amps) will be very different from the current that should be applied for recharging a mobile phone battery (250 mA to 1000 mA). However, solar cell output current can be utilized to charge any battery.

In many areas, especially where electrical power is unavailable or unreliable, there is a need for devices that are capable of powering user devices such as lights, radios, MP3 players, cell phones, or other devices, or are capable of charging batteries directly.

### SUMMARY

In accordance with the present invention, a personal solar appliance according to some embodiments of the present invention can include a base with ventilation holes; a heat sink coupled to the base; at least one solar cell mounted to the heat sink opposite the base; a printed circuit board mounted to the heat sink opposite the solar cell; and a battery mounted to the base.

A method of forming a personal solar appliance according to some embodiments of the present invention includes affixing a printed circuit board to a bottom of a heat sink; affixing a solar cell to a top of the heat sink; attaching the heat sink to a ventilated base; and attaching a battery to the base opposite the heat sink.

These and other embodiments are further discussed below with reference to the following figures, which are incorporated in and considered a part of this disclosure.

### BRIEF DESCRIPTION OF THE FIGURES

FIG. 1 illustrates a personal solar appliance according to some embodiments of the present invention.

FIGS. 2A and 2B illustrate a personal solar appliance according to some embodiments of the present invention.

FIG. 3 illustrates a personal solar appliance with a solar concentrator according to some embodiments of the present invention.

FIGS. 4A, 4B, and 4C illustrate a base of a personal solar appliance according to some embodiments of the present invention.

FIGS. 5A and 5B illustrates assembly of the components of a personal solar appliance according to some embodiments of the invention.

FIGS. 6A and 6B illustrate assembly of the components of a personal solar appliance according to some embodiments of the invention.

FIGS. 7A and 7B further illustrate assembly of the legs of a personal solar appliance according to some embodiments of the present invention illustrated in FIG. 6.

FIGS. 8A and 8B illustrate aspects of a top cover of a personal solar appliance according to some embodiments of the present invention.

FIGS. 9A through 9D illustrates assembly of certain components of the personal solar appliance illustrated in FIG. 6.

In the figures, components having the same designation have the same or similar function. In the figures, components are not drawn to size.

### DETAILED DESCRIPTION

Aspects of various embodiments of PSA according to the present invention are described below. One skilled in the art will recognize that particular embodiments of PSA according to the present invention can include any number of the individual features that are described. Further, one skilled in the art may recognize various modifications or alternatives to the particular embodiments described here. Those modifications and alternatives are intended to be within the scope of the present disclosure.

In some embodiments, the PSA is rugged. In some embodiments, the PSA is a waterproof device. In some embodiments, the PSA includes photovoltaic cells, a battery, a connector to extract power from the PSA, and electronics to manage the power and charging of the battery. In some embodiments, the PSA includes status indicators to provide information on the photovoltaic performance and the battery charge state. In some embodiments, the PSA includes reflectors to increase energy production. In some embodiments, components of the PSA, for example the device's legs, reflectors, battery, and electronics, can be user replaceable.

In some embodiments of a PSA according to the present invention, the PSA can include one or more solar cells; electronics coupled to the one or more solar cells; and a battery coupled to the electronics for storing the photovoltaic energy. In some embodiments, the electronics performs power, charge, and telemetry management. In some embodiments, the PSA further includes a system of cables and connectors to couple with user devices.

U.S. patent application Ser. No. 12/340,500, which is herein incorporated by reference in its entirety, describes a concentration system, a liquid crystal display or similar type display, and a customizable reflective layer to provide visual appeal for a device with a photovoltaic system. U.S. patent application Ser. No. 12/351,105, which is herein incorporated by reference in its entirety, describes an intelligent protective case with photovoltaic, battery, and electronics for use by an intelligent user device. U.S. patent application Ser. No. 12/351,105 also describes the architecture whereby software is obtained and installed for use on the intelligent user device including utilization of the Internet. A discussion of the charging electronics is provided in U.S. patent application Ser. No. 12/831,932, filed on Jul. 7, 2010, which is herein incorporated by reference in its entirety.

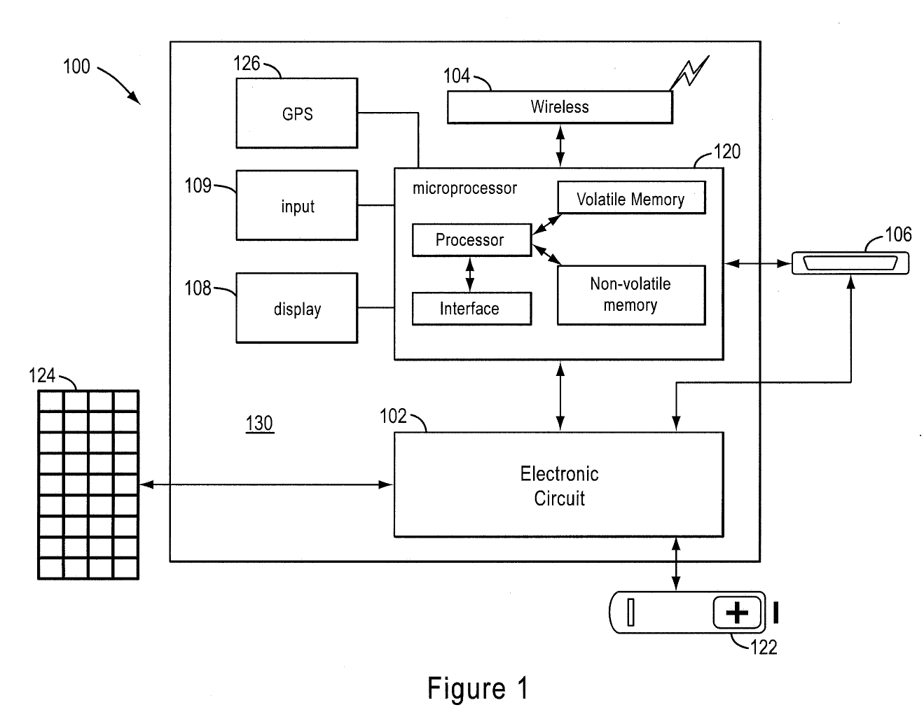

FIG. 1 illustrates an embodiment of intelligent charger 100 consistent with the present invention. Intelligent charger 100 includes one or more solar panels 124, a battery pack 122, and electronics 130. Electronics 120 includes a microprocessor 120 and electronic circuit 102 and controls the charging of battery 122 from solar cell 124. As shown in FIG. 1, microprocessor 120 can include a processor, volatile and non-volatile memory, and an interface. Programming and operating parameters can be stored in non-volatile memory while operating parameters and interim results can be stored in volatile memory. The interface allows microprocessor 120 to communicate, for example with wireless transceiver 104, physical connector 106, and electronic circuit 102. In some embodiments, intelligent charger 100 may include a display 108 and may further include a user input device 109 in order to communicate with a user. Additionally, microprocessor 120 may receive location data through a GPS device 126, which can be communicated either through connector 106 or through transceiver 104.

As shown in FIG. 1, microprocessor 120 is coupled to electronic circuit 102. Electronic circuit 102 is coupled to solar panel 124 and battery pack 122. In some embodiments, electronic circuit 102 can use a boost or buck mode of power management to output current and voltage compatible with battery 122 based upon incoming current and voltage from solar panel 124. Battery 122 can be any rechargeable battery, but in some embodiments is a lithium-ion polymer. Electronic circuit 102 is also coupled to physical connector 106 in order to provide a charging current and voltage to an external device (not shown) that is coupled to connector 106.

Electronic circuit 102 is coupled to microprocessor 120, which stores and executes charge management software. The charge management software operating on microprocessor 120 ensures that battery pack 122 and any battery coupled to connector 114 receives current and voltage appropriate to charge those batteries. As such, electronic circuit 102 receives power from solar panel 124 and converts that power to voltage and current appropriate to charge battery pack 122. Electronic circuit 102 may also convert power to voltage and current appropriate to charge a battery pack coupled to connector 106.

In some embodiments, electronic circuit 102 also includes monitoring electronics to monitor the power output and status of solar panel 124 as well as the charge and status of battery 122. In some embodiments, electronics 102 can also monitor the charge and status of a battery in a device coupled to connector 106. Microprocessor 120, then, can monitor and provide statistics on, for example, power production in solar panel 124, temperature, and battery charging.

As shown in FIG. 1, intelligent charger 116 may also include a wireless transceiver 104 that is coupled to microprocessor 120. Wireless transceiver 104 may include a cell phone transceiver and may be capable of communicating directly to servicers coupled to the internet. In some embodiments, wireless transceiver 104 may include a local transceiver such as, for example, a Bluetooth transceiver. In which case, intelligent charger 116 can communicate wirelessly smart devices or to personal computers through wireless transceiver 104.

In some embodiments, information regarding charging or discharging of battery 122 may be displayed on display 108. In some embodiments, a smart device coupled to connector 106 may communicate information to electronic circuit 102 that may then be displayed on display 108. Several status parameters can be provided on display 108. In some embodiments, display 108 may be a liquid crystal or electronic paper device. Status information that may be displayed can include, for example, power produced by the solar cells, state of charge of the internal battery, power drawn by an external device, or any other parameter.

In some embodiments, an input device 109 can also be included. Input device 109 may be, for example, an electrostatic touch sensor or other user input device may be utilized so that a user may request status information from the PSA.

In some embodiments, the PSA can include a global positioning system (GPS) 126 to determine its position. In some embodiments, the PSA can also include a transceiver 104 that can communicate with a remote system via wireless communications or an internet link in order to report its position and status. In some embodiments, the PSA can report to the remote system when prompted by the remote system. In some embodiments, the PSA can report its position and a fault condition to the remote system. A telemetry system that can be utilized for connecting the PSA to a remote monitoring system is described in U.S. patent application Ser. No. 12/351,105. In general, position, statistical data, or fault conditions can be reported to a remote monitor.

Connector 106 of PSA 100 can be utilized to provide power, telemetry, and configuration management. Connector 106 can be one or more of the families of USB connectors (microUSB, miniUSB, and USB), which may be appropriately protected for outdoor protection when used on PSA 100. The USB family is able to perform telemetry functions from the PSA and enables the PSA to be configured by a remote computer. Power is delivered by the PSA using a female axial power connector that, in some embodiments, is waterproof and structurally strong. The non-PSA side of the cable may have a number of different devices to receive the power. The power supplied could be at a number of different voltages. The USB family is supplied 5 V at 500 mA to 1000 mA. A cigarette lighter adaptor would take over 13 V at several amps if possible. Other variations are possible. In order to determine what voltage and current should be provided, the PSA can use a sense resistor on a cable pin to determine the nature of the load and dynamically adjust the voltage of its power output accordingly.

Some embodiments of PSA 100 according to the present invention provide for charging of battery 122 in any charge state, including completely discharged, from solar cell 124 with no other source of power provided. Such a charging system has been described in U.S. application Ser. No. 12/831,392.

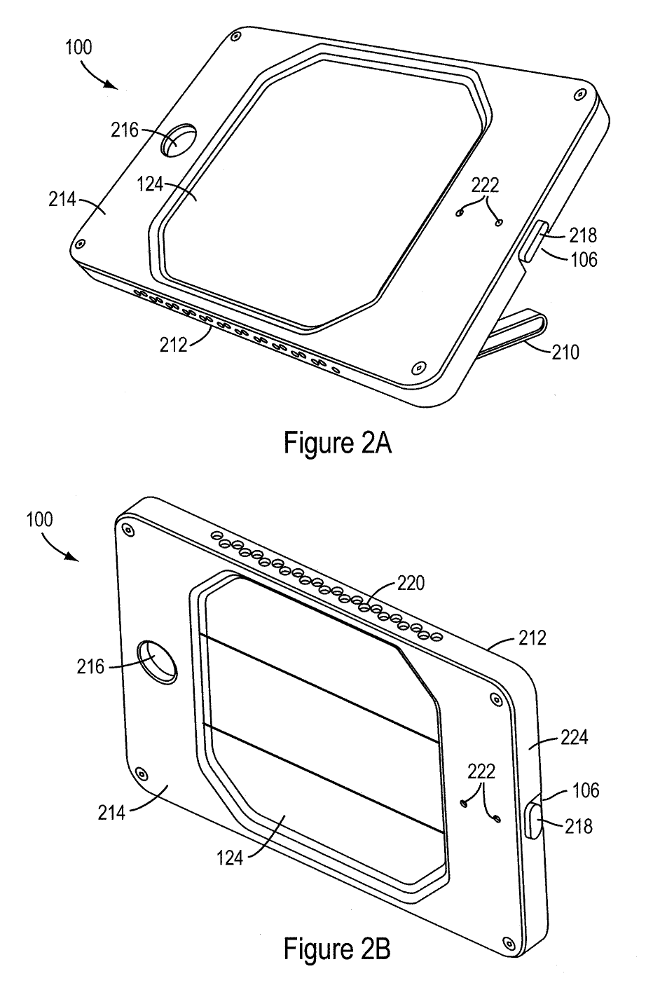

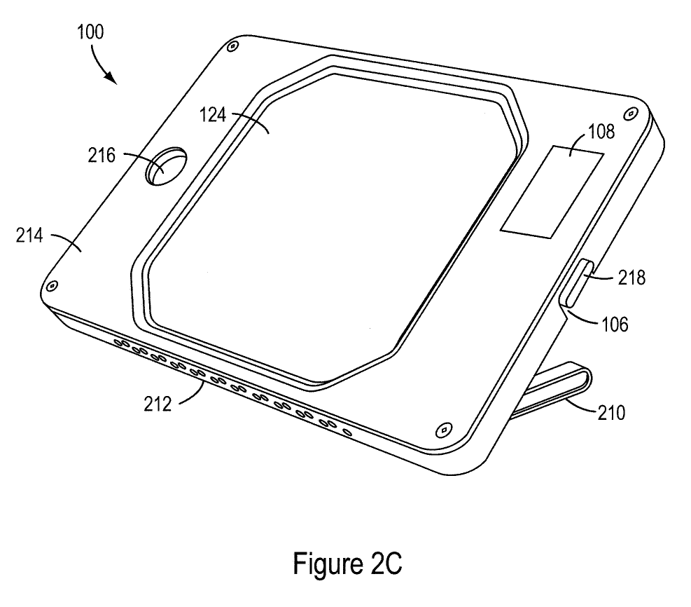

FIGS. 2A and 2B illustrate an example of PSA 100 according to some embodiments of the present invention. As shown in FIG. 2A, PSA 100 includes a base 212 and a top cover 214. Base 212 houses the electronics shown in FIG. 2A as well as solar cell 124. Cover 214 attaches to base 212 and covers solar cell 124. Further shown in FIG. 2A is connector 106, which is covered by a protective covering 218. Further, PSA 100 may include foldable legs 210 that can be adjusted to position PSA 100 for best collection of solar radiation. In some embodiments, foldable legs 210 open to locking positions and are attached to base 212 using detents that allow movement of legs 210 in one direction. In some embodiments, legs 210 lock into place at locations designed to provide optimal photovoltaic performance depending upon the PSA's latitude or the amount of daily solar variation encountered.

Further, one or more mounting holes 216 may be included to allow PSA 100 to be firmly attached to another platform. Further, in some cases, a locking mechanism (for example a chain and lock) can be provided to fix PSA 100 to an external structure through mounting holes 216.

As is further shown in FIG. 2A, PSA 100 may include indicator access 222 through which lighted indicators can be viewed. In general, indicator access 222 can provide access for the viewing of any number of indicator lights. Further, although not shown in the embodiment shown in FIG. 2A, access cover 214 may further include access for viewing of display 108

FIG. 2B illustrates a slightly different perspective of the embodiment of PSA 100 illustrated in FIG. 2A. In FIG. 2B, ventilation holes 220 in base 212 are shown. Further, ventilation 224 under top cover 214 is shown. Ventilation holes 220 and 224 provide cooling for PSA 100 by providing cooling flow for electronics and, through top cover 214, providing cooling to solar cell 124.

FIG. 2C illustrates an embodiment of PSA 100 that includes a display 108. Display 108 can be visible through cover 214, as shown in FIG. 2C. Display 108 can be positioned anywhere on the face of PSA 100. Some embodiments of the invention can utilize both display 108 and indicators 222.

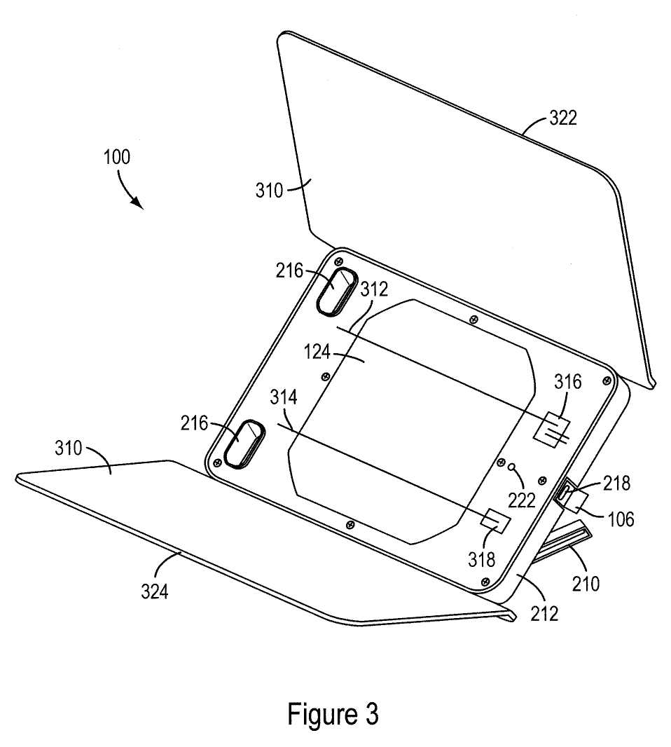

FIG. 3 illustrates another embodiment of PSA 100 that includes a solar concentrator 310. Solar concentrator 310, as shown in FIG. 3, includes reflectors 322 and 324 that concentrate solar radiation onto solar cell 124. The dominant cost in any solar energy system is the solar cells. By comparison reflective materials such as reflectors 322 and 324, whether made out of metals, Mylar, or other materials, are very inexpensive. Increasing the amount of incoming solar radiation by using reflectors 322 and 324, therefore, can make economic sense.

Reflectors 322 and 324, if made of a heat conductive material, may provide a heat sink capability for PSA 100. There are several reasons why this matters. The performance of solar cell 124 degrades as its temperature warms, so keeping solar cell 124 cool improves its performance. Electronics 130 may fail if the temperature gets too warm as they are typically the weakest link from a temperature perspective with circuits starting to fail when the temperature rises above 65° C. In some embodiments, reflectors 322 and 324 can dissipate a large amount of heat in order to help cool PSA 100.

For a given solar cell, the size of reflectors 322 and 324 and their orientation to the plane of the solar cell are important considerations. Studies of the performance of reflectors have shown that a pair of reflectors 322 and 324, each twice as long as solar cell 124, and mounted at a 60° angle relative to the plane of solar cell 124 represent an optimal arrangement with PSA 100 oriented north/south. In some embodiments, reflectors 322 and 324 are twice as long as solar cell 124. In some embodiments, reflectors 322 and 324 are mounted at an angle of about 60° from the plane of solar cell 124. In some embodiments, reflectors 322 and 324 are centered on the plane of solar cell 124. In some embodiments, PSA 100 can be oriented such that solar cell 124 is oriented north/south such that reflectors 322 and 324 are in the east/west position.

FIG. 3 illustrates an embodiment of PSA 100 with reflectors oriented at about a 60° angle to solar cell 124 and which are twice the length of solar cell 124. Although these parameters are utilized in the specific embodiment, one skilled in the art will recognize that other shapes and orientations may also function. Further, in some embodiments, reflectors 322 and 324 may be shaped to provide focusing of light onto a smaller solar cell surface.

As is further shown in FIG. 3, mounting holes 216 can include multiple mounting holes. Further shown in FIG. 3 are electrical connections 312 and 314 from solar cell 124 to a circuit board at connections 316 and 318. In some embodiments, solar concentrator 310 may be added or removed to the photovoltaic system. In some embodiments, the reflectors of solar concentrator 310 possess an optimal geometry with respect to the solar cell.

Some embodiments of PSA 100 provide solar charging capability of small appliances in sometimes severe environmental conditions. Therefore, some embodiments of PSA 100 are structurally strong and resist damage due to rough handling and rough conditions. Further, some embodiments of PSA 100 are waterproof to resist damage due to water immersion or wet conditions.

A solar cell, such as solar cell 124, which may be utilized in PSA 100, is expected to have a long lifetime. Expectations of over 20 years for solar cell 124 are not unreasonable if PSA 100 is not mistreated. However, electronics 130 and battery 122 are both expected to have different lifecycles which are significantly shorter than that of solar cell 124. In some embodiments, components like reflectors 322 and 325, batteries 122, legs 210, and electronics 130 can be individually replaceable in order that the lifetime of PSA 100 is not limited to the shortest lifetime component.

In some embodiments, PSA 100 as shown in FIGS. 1, 2A, 2B, and 3 includes one or more solar cells 124, a battery 122, electronics 130 coupled to store photovoltaic energy from the one or more solar cells in the battery, and a structurally resilient base 212 that houses the one or more solar cells 124, the electronics 130, and the battery 122. In some embodiments, the PSA further includes reflectors 322 and 324 coupled to the base to increase solar power incident on the one or more solar cells 124.

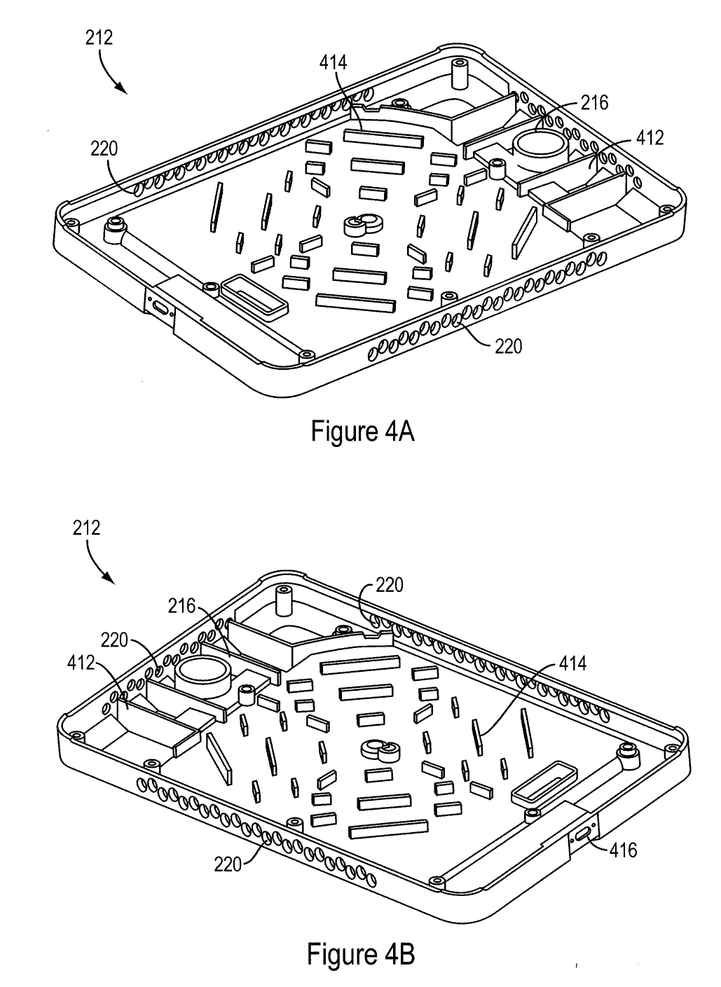

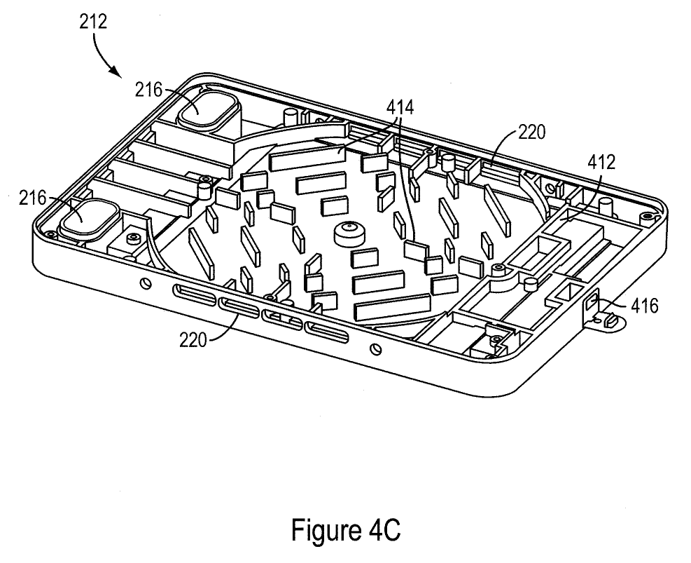

FIGS. 4A, 4B, and 4C illustrate embodiments of a base 212 according to some embodiments of the invention. As shown, base 212 can be formed of polycarbonate and includes ventilation holes 220 for heat dissipation. In some embodiments, solar cell 124, battery 122, and electronics 130 are mounted to base 212, as shown below. In some embodiments, base 212 includes rib supports 414 and 412 on which a plate can be fixed. Supports 412 and 414 distribute any load stress placed on PSA 100 to base 212. As is further shown, base 212 includes one or more holes 216 for the purpose of securing PSA 100 to an external structure. Further, base 212 can include a mount 416 to hold connector 106. In addition, rib supports 414 and 412 can be placed to facilitate the flow of air through base 212, thereby more efficiently cooling PSA 100. Support ribs 412 provide further support and structure on which a plate (not shown) that includes some further components of PSA 100 can be mounted.

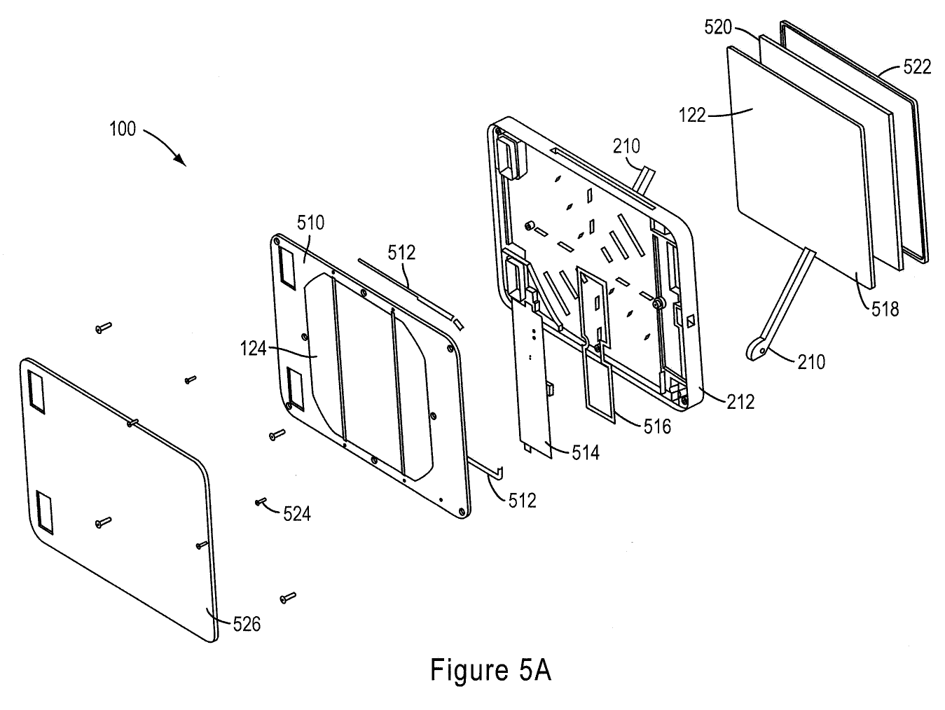

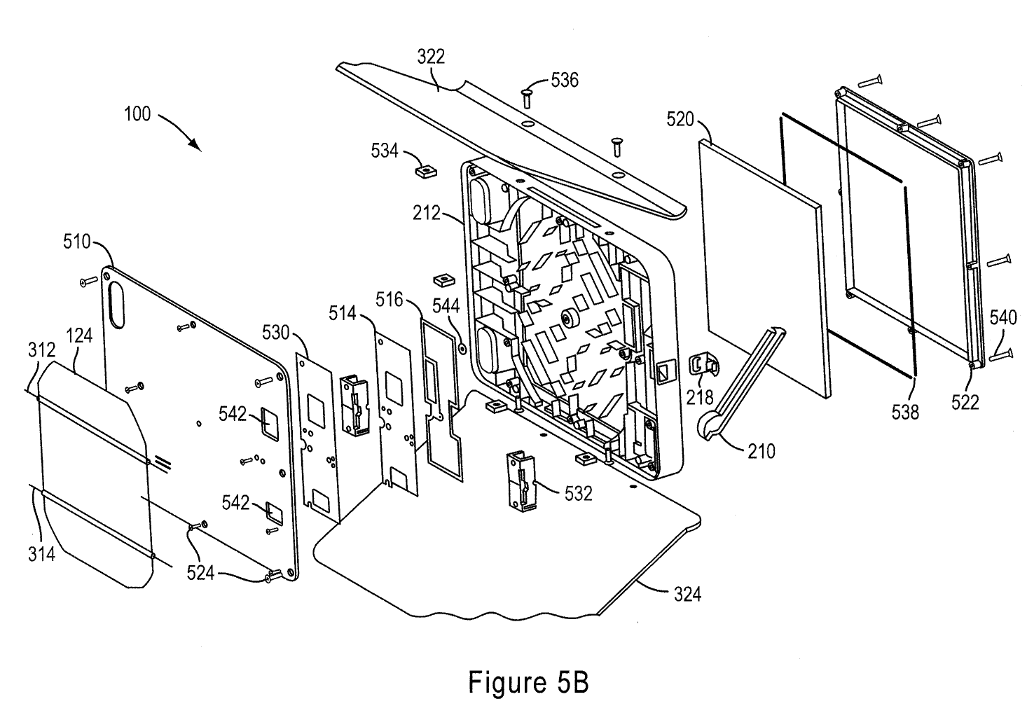

FIGS. 5A and 5B illustrate assembly of a PSA 100 according to some embodiments of the invention. As shown in FIG. 5A, solar cell 124 is mounted on a heat sink 510 and electrically coupled to wiring 512. Wiring 512 is coupled to printed circuit board (PCB) 514, that is mounted onto heat sink 510. Heat sink 510 and circuit board 514 are mounted in base 212. In some embodiments, an o-ring seal 516 is made between PCB 514 and base 212 in order to provide a water proof environment for the electronics on PCB 514. Electronics 130 is at least partially included on PCB 514. Legs 212 are mounted to base 210. As shown in FIG. 5A, heat sink 510 can be attached to base 212 with screws 524. Battery 122, which can include a base plate 518, battery component 520, and cover 522, are mounted in base 212 opposite heat sink 510. In the embodiment shown in FIG. 5A, cover 526, which may be a polyurethane sheet or may be cover 214, is mounted over heat sink 510 in order to cover solar cell 124.

FIG. 5B illustrates another assembly of a PSA 100 according to some embodiments of the present invention. As shown in FIG. 5B, solar cell 124 is mounted on heat sink 510. Leads 312 and 324 are coupled to circuit board 514 through access holes 542. A metal plate gasket 530 is mounted between circuit board 514 and heat sink 510. Heat sink 510 is screwed into base 512 with screws 524. Gasket 516 helps seal the electronics on PCB 514. Further, a resin injection gasket 544 can be included to help in potting the electronics. Reflectors 322 and 324 can be screwed into base 212 with screws 536 and nuts 534. In the embodiment shown in FIG. 5B, battery 520 is placed in base 212 and sealed in place with gasket 538 between base 212 and cover 522. Cover 522 is mounted to base 212 with screws 540.

Some embodiments of PSA 100 according to aspects of the present invention can withstand shocks. In particular, these embodiments may withstand shear forces which are parallel or tangential to the face of solar cell 124. Some embodiments of the PSA may also withstand normal forces which are perpendicular to the face of solar cell 124. These forces can be visualized as dropping the PSA from a height, or riding over the PSA with a cart, for example. In some embodiments, PSA 100 dissipates heat. In some embodiments, the one or more solar cells 124 are encapsulated with a resin (for example, urethane) to a metal substrate heat sink 510. In some embodiments, the thickness of the resin is determined by the Young's modulus (E) and Poisson ratio of the resin.

Solar cell 124 itself is as delicate as a potato chip. Without proper protection, solar cell 124 will crack and become nonfunctional. As shown in FIGS. 5A and 5B, solar cell 124 is attached to a heat sink 510. Heat sink 510 can be made from steel, although other substances such as a tin-aluminum alloy may be utilized. In some embodiments, solar cell 124 is bonded to heat sink 510 using a very hard resin. As shown, heat sink 510 can then be mounted on a base 212, which can be a polycarbonate base with supports 414 and 412 that deflect any loading stress to the bottom of PSA 100. Solar cell 124 and heat sink 510 together can be encapsulated with a resin of urethane 526, as shown in FIG. 5A.

This encapsulation of solar cell 124 with urethane achieves several things: It protects solar cell 124 from environmental factors; It allows light to reach solar cell 124 because resin cover 526 has a high transmissivity and permits light of the right wavelength to hit solar cell 124; It performs heat conduction to heat sink 510, thereby cooling solar cell 124; and It will self heal small scratches over time. In some embodiments, the gap between solar cell 124 and the heat sink 510 can be minimized, maximizing thermal transfer and keeping the temperature of solar cell 124 down. The metal plate of heat sink 510 can dissipate heat into ventilated base 212. However, the gap between solar cell 124 and heat sink 510 can not be too small otherwise the urethane will transfer too much stress, which results from the thermal expansion of heat sink 510, to solar cell 124. Under stress, solar cell 124 may form cracks.

Embodiments of PSA 100 can be constructed with many mechanical factors in mind: shear modulus G of cover 526; Young's modulus of solar cell 124; Young's modulus of heat sink 510; coefficient of thermal expansion of solar cell 124; and the coefficient of thermal expansion of heat sink 510. In some embodiments, the various factors can be balanced to protect solar cell 124 from the environment and to maximize the transmissivity of light to solar cell 124. Because light heats solar cell 124, the heat should be diverted as much as possible to prevent the degradation of the performance of solar cell 124. To dissipate the heat effectively, heat sink 510 should be excellent at thermal conduction, should be mechanically strong, and should have a low coefficient of thermal expansion. A metal substrate such as steel or aluminum has many of these characteristics. Steel is heavier but does not thermally expand as much as aluminum. Aluminum is lighter, but expands nearly twice as much as steel.

The gap between solar cell 124 and heat sink 510, the mechanical properties of the urethane, and the mechanical properties of heat sink 510 can all be varied. As a heat sink, aluminum expands twice as much as steel, however steel is heavier. All other variables are fixed: solar cell yield strength, the solar cell's Young's modulus, and the thermal coefficient of expansion of the solar cell. Once the substrate material for heat sink 510 is chosen, the substrate's Young's modulus, and the substrate's coefficient of thermal expansion are also fixed parameters. However, the thickness and composition of the urethane can still be modified.

The Young's modulus and the Poisson ratio of the urethane separating solar cell 124 and heat sink 510 determine the size of the gap (e.g., the thickness of the urethane). Young's modulus (E) is a measure of the stiffness of an isotropic elastic material. Modulus E is the ratio of stress, which has units of pressure, to strain, which is dimensionless. Therefore, Young's modulus itself has units of pressure. Poisson's ratio is defined as the ratio of the relative contraction strain, or transverse strain, normal to the applied load to the relative extension strain, or axial strain, in the direction of the applied load. The general formula for sheer modulus G, which describes a material's response to shearing strains, is G (shear modulus)=E (Young's modulus)/2(1+Poisson's ratio)=(F/A)(d/x), where F/A is the pressure applied (for example due to thermal expansion), d is the initial thickness of the urethane resin, and x is the lateral displacement of the urethane resin due to the stress. Ideally, the urethane resin should be hard to the touch and hard to scratch, but not so hard that the Young's Modulus gets larger, which in turn can increase the desired thickness of the urethane resin.

Additionally, as is shown in FIGS. 4A, 4B, and 4C, in some embodiments heat sink 510 is supported against a series of supports 414 and 412 in base 212 in order that forces applied to PSA 100 do not bend heat sink 510, and thereby crack solar cells 124. In some embodiments, base 212 is structurally resilient to help withstand rough handling. In some embodiments, base 212 can be formed of polycarbonates. Polycarbonates are a particular group of thermoplastic polymers. They are inexpensive, easily worked, molded, and thermoformed. Polycarbonates have temperature and impact resistance. Injection molded polycarbonates are very strong. Typical mechanical properties of a polycarbonate for forming a base such as that shown in FIGS. 4A, 4B, and 4C are as follows: the Young's modulus (E) of 2-2.4 GPa, tensile strength (σt) of 55-75 MPa, and compressive strength (σc)>80 MPa. The thermal properties of a typical polycarbonate material are as follows: working temperature range is from 130° C. to −135° C., the linear thermal expansion coefficient (σ) is 70×10⁻⁶/K, the specific heat capacity (c) is 1.3 kJ/kg·K, the thermal conductivity (k) at 23° C. is 0.21 W/(m·K), and the heat transfer coefficient (h) is 0.21 W/(m²·K).

In some embodiments, as shown in FIGS. 4A, 4B, and 4C supports 414 provided by base 212 are arranged to provide air flow cooling to the back of heat sink 510 in order to help cool PSA 100. In addition to the physical stresses applied to solar cells 124 by temperature changes, the efficiencies of solar cells 124 are affected by heat. As the cells warm they become less efficient. A typical degradation in efficiency percentage would be −0.41% per ° C. for temperatures above 25° C. On Sep. 13, 1922, a temperature of 136° F. (57.8° C.) was recorded in the city of Al 'Aziziyah, Libya. This is the highest temperature ever recorded. Assuming PSA 100 can be kept at thermal equilibrium the worst case environmental circumstance would be about 58° C. In some embodiments of the invention, thermal load management by PSA 100 can be an important issue.

As shown in 2B and 4A, 4B, and 4C, some embodiments of PSA 100 have positioned vents 220 and supports 414 to provide for air circulation through PSA 100 under heat sink 510. The base also holds battery 122 and electronics 130, which may also be cooled with vents 220 and supports 414.

In addition, some embodiments of PSA 100 can be waterproof. This is illustrated in FIGS. 5A and 5B where various gaskets and seals are shown in the construction. In some embodiments, for example, a NEMA classification of 6P can be achieved, providing for a PSA 100 that can be submersible to a depth of several feet. As shown in FIG. 5B, battery 122, which can be a lithium-ion polymer, can be kept in a watertight compartment formed by base 212 and cover 522 with a rubber gasket 538 as a seal. When battery 122 is replaced, the entire battery cover 522 with a new rubber gasket 538 can be installed. In some embodiments, PSA 100 can have positive buoyancy in water so that it floats.

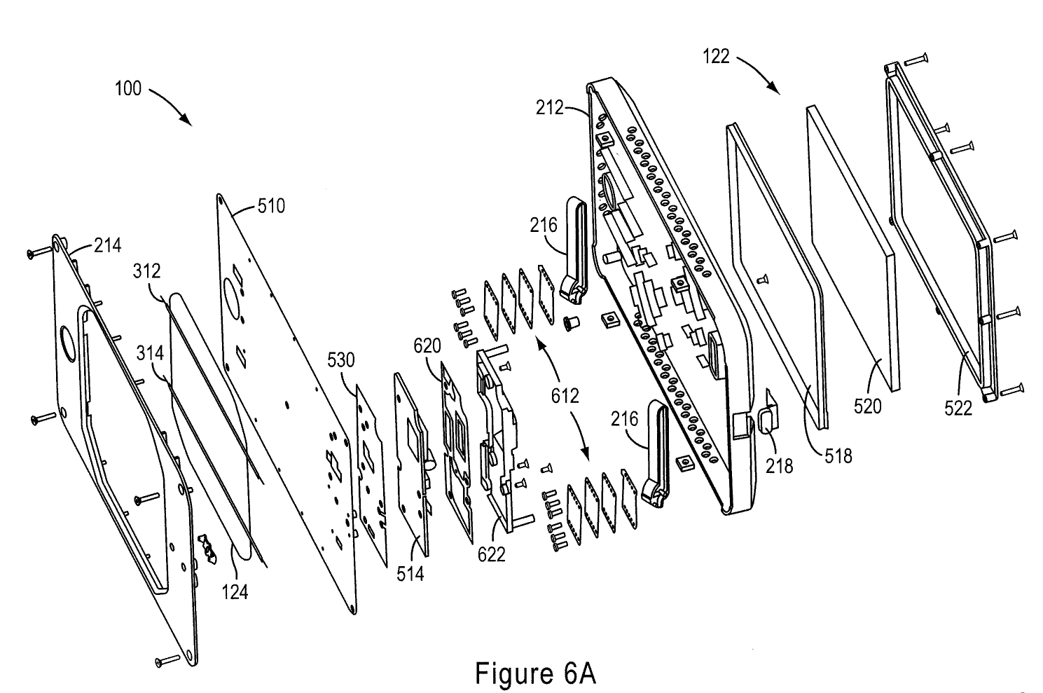

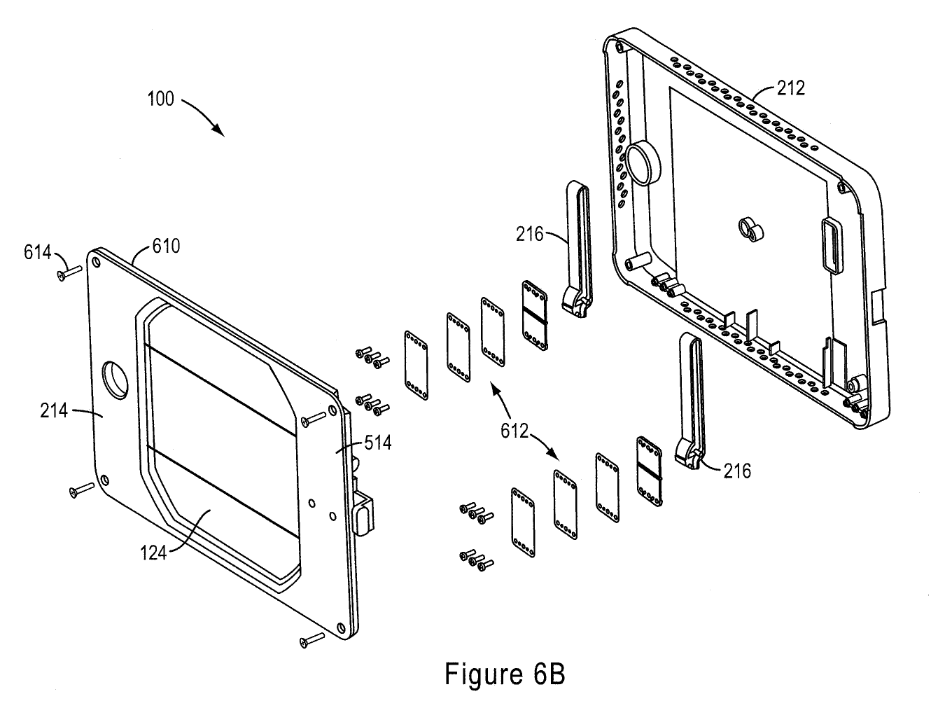

FIG. 6A illustrates assembly of PSA 100 according to some embodiments for the present invention. As shown in FIG. 6A, solar cell 124 and PCB 514 can be mounted to heat sink 510. A metal gasket 530 may be placed between PCB 514 and heat sink 510. A gasket 620 can be placed over PCB 514 and PCB 514 be covered with cover 622. The electronics on PCB 514 may be potted through cover 622. Solar cell 124 may be epoxyed to heat sink 510 and then encapsulated with, for example, a urethane layer over solar cell 124. As shown in FIG. 6A, cell leads 312 and 314 are coupled to solar cell 124 and connected to PCB 514 during the assembly process. Cover 214 may then be placed over heat sink 510 and the assembly connected, for example by screws, to base 212.

As further illustrated in FIG. 6A, foot assembly 612 and legs 610 may also be provided. Foot assembly 612 can include plastic detents 532 as shown in FIG. 5B, or may include metal spring parts as illustrated in FIG. 6A. Once assembled, a connector cover 218 can be inserted into base 212.

As shown in FIG. 6A, battery 122 includes a base 518, a battery component 520, and a cover 522. Battery 122 can be inserted into the bottom of base 212 and screwed into place through cover 522.

FIG. 6B further illustrates assembly of PSA 100 according to some embodiments of the present invention. As shown in FIG. 6, PSA 610 is formed by cell assembly 610, foot assembly 612, legs 216, and base 212. A battery 122 such as that shown in FIG. 6A is also included. As shown in FIG. 6B, cell assembly 610 includes solar cell 124 and PCB 514. Further, cell assembly 610 can include cover 214.

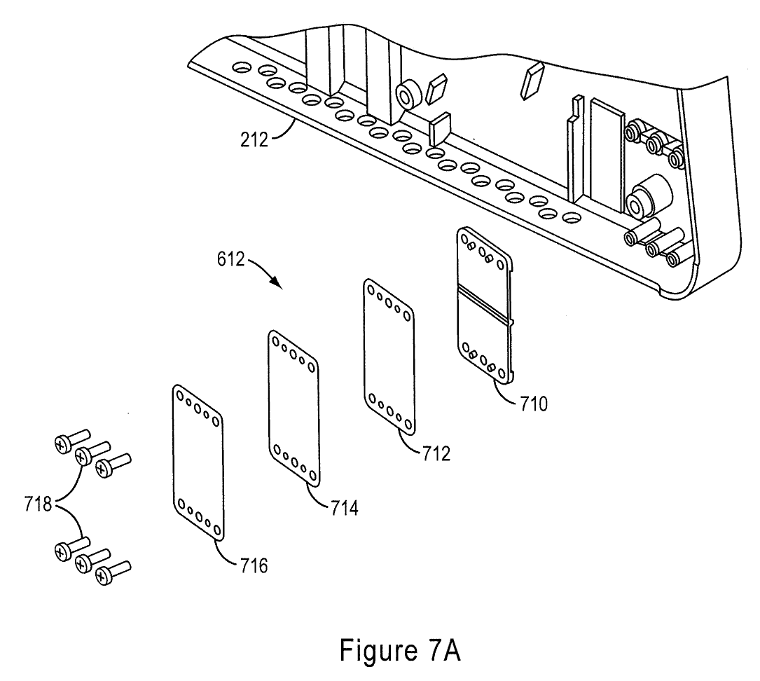

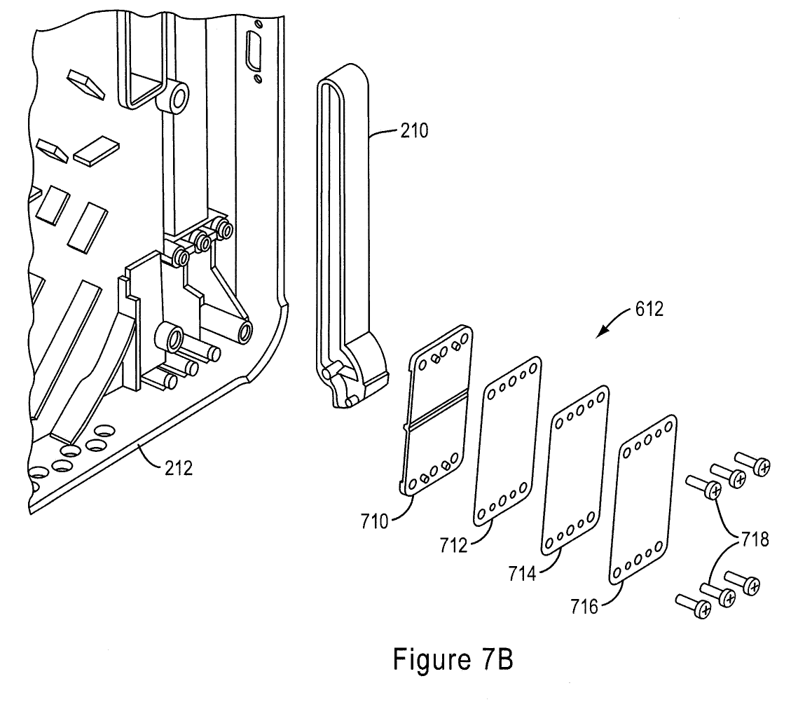

FIGS. 7A and 7B illustrate foot assembly 612 according to some embodiments of the present invention. As shown in FIG. 5B, legs 210 can be mounted with detents 532. Detents 532 can be formed from plastic or from metal. Foot assembly 612 shown in FIGS. 6, 7A, and 7B provide a more robust mounting for legs 212. The leg supports 212 for PSA 100 should be robust and undergo extension and retraction multiple times over the lifetime of the PSA. Foot assembly 612 includes several metal springs 712, 714, and 716 along with a foot detent 710, which can be made from spring metal or from spring plastic. Metal springs provide a substantially increase in the lifecycle of detent 532 over plastic. Metal springs 712, 714, and 716 along with detent 710 can be held in place by screws 718 to base 212. Legs 212 are held in place by springs 710, 712, 714, and 716.

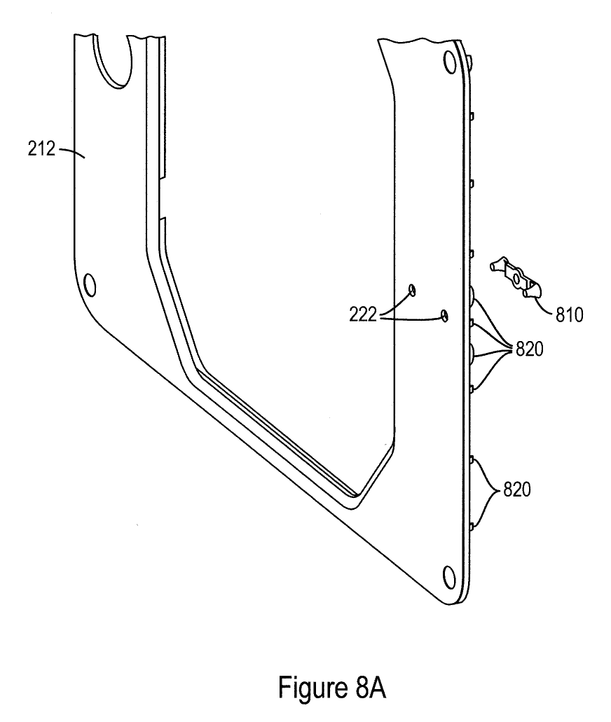

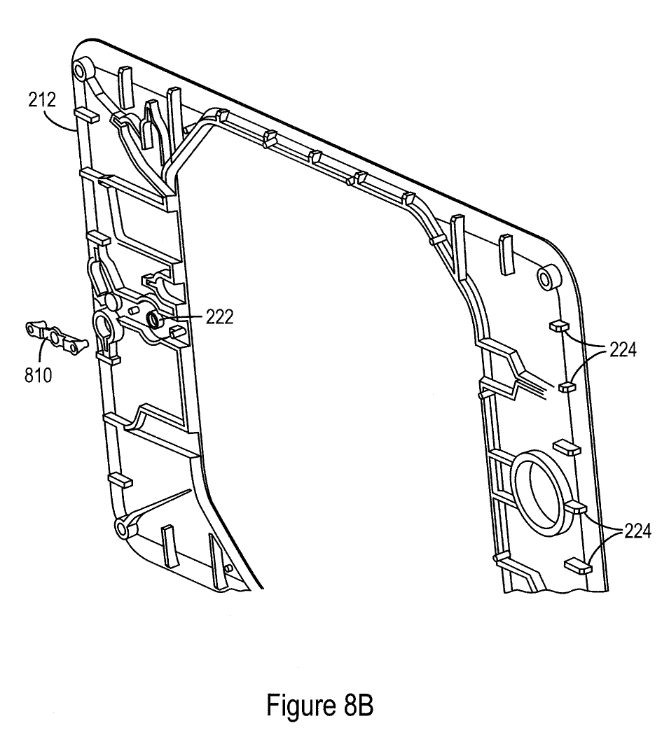

FIGS. 8A and 8B illustrate utilization of a light pipe 810 to carry light from printed circuit board 514 through cover 212 to indicates 222. Light pipes 810 can be utilized to carry colored LED light signals from electronics on printed circuit board 514 through cover 212 so that they are visible to a user. In some embodiments, light pipes 810 can be potted with urethane.

As is further illustrated in FIGS. 8A and 8B, cover 212 may include ventilation access 820. Ventilation access 224 allow for cooling of the front side of solar cell 124 during operation. Top cover ventilation helps to keep PSA 100 at ambient temperature. With base 212 ventilated with vent holes 220, top portion vents 224—help to prevent additional heat buildup. Solar cell performance declines with increasing heat and therefore additional ventilation can help improve performance. The PSA top cover 212 can be ventilated on each side and can be anchored to PSA 100 with screws at each corner. The top cover can further be attached to PSA 100 when solar cell 124 is encapsulated with urethane adding additional stability.

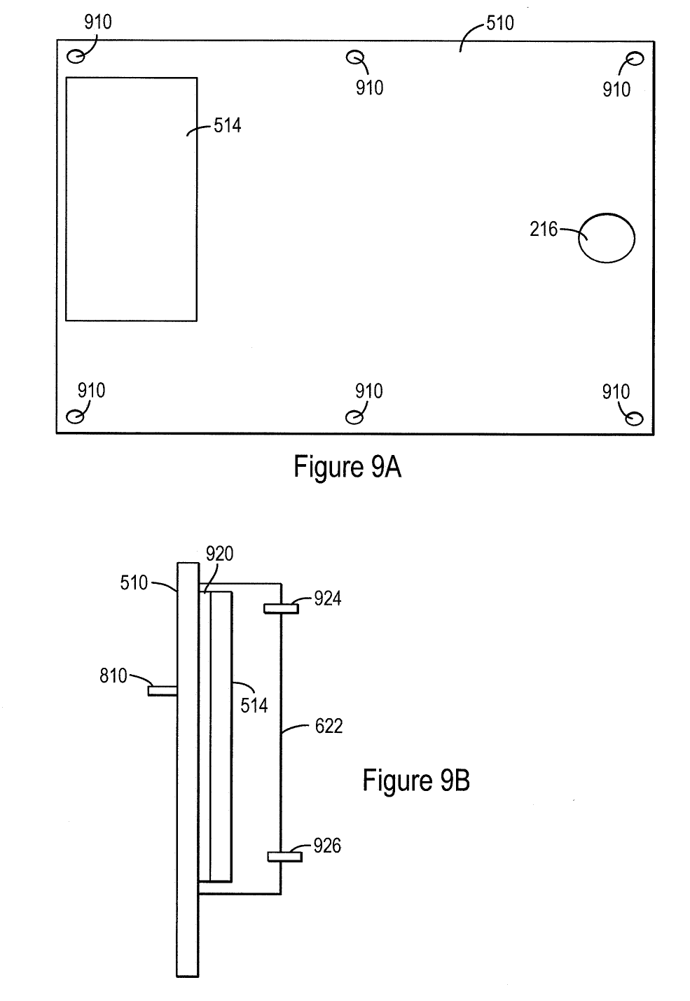

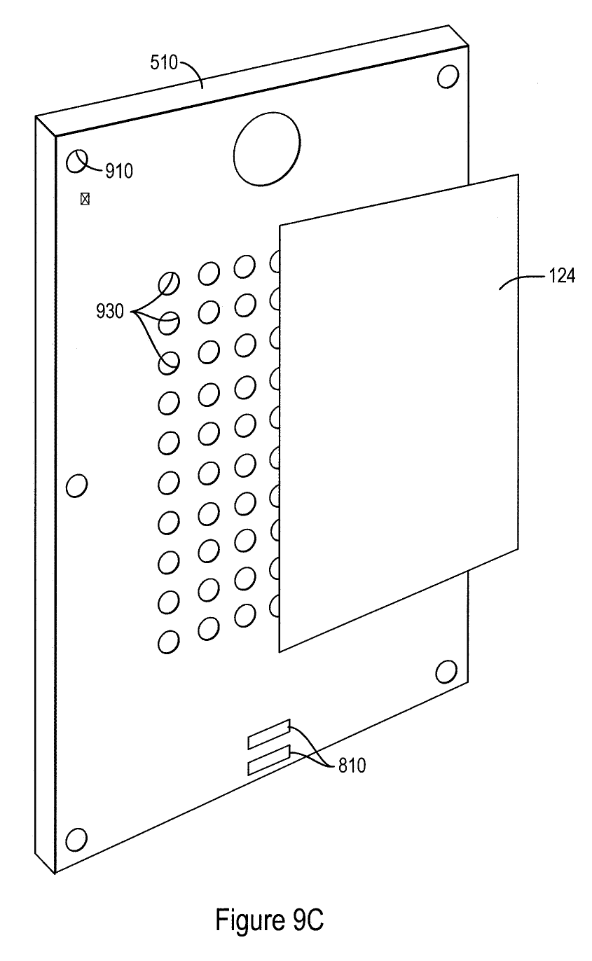

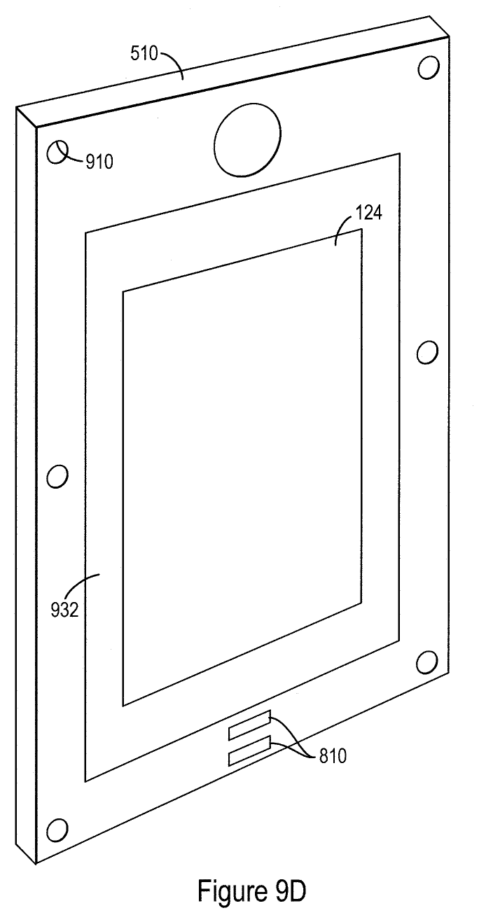

FIGS. 9A, 9B, 9C, and 9D illustrate formation of cell assembly 610 according to some embodiments of the present invention. FIGS. 9A and 9B illustrate mounting of PCB 514 on heat sink 510 while FIGS. 9C and 9D illustrate mounting of solar cell 124 on the opposite side of heat sink 510.

The electronics of PSA 100 can be potted. In electronics, potting is a process of filling a complete electronic assembly with a solid compound for a specific purpose. Thermosetting plastics are typically used, and some embodiments of PSA 100 include a colored thermo-plastic potting material. In some embodiments, the PSA electronics can resist both shock and vibration. In addition, the electronics can be immune from the effects of moisture and corrosive agents. Potting will exclude these to a great extent. Another rational for potting has to do with replacement. When the electronics fail they can be replaced. Potted electronics will be easier to handle throughout this process. Using a colored potting agent will provide a level of security with respect to the electronics design and the components used.

As shown in FIG. 9A, circuit board 514 is mounted on heat sink 510. Heat sink 510 includes through holes 910 for mounting to base 212 and mounting hole 216 as described above. FIG. 9B shows a cross sectional view of PCB 514 mounted to heat sink 510. As shown in FIG. 9B, PCB 514 can be attached to heat sink 510 with an epoxy layer 920, or layer 920 may be a metal gasket 530 as shown in, for example, FIG. 6A. In general, PCB 514 can be affixed to heat sink 510 in any way, including screwing PCB 514 into heat sink 510. As shown in FIG. 9B, light guide 810 can be mounted to printed circuit board 514 as PCB 514 is mounted to heat sink 510. A cover 622 can be placed over PCB 514. Cover 622 can include holes 924 and 926 to serve as vent and access for potting. In general, there can be any number of holes 924 and 926.

Cover 622 creates a small but sufficient volume for urethane to pot the electronics on PCB 514. Cover 622 is placed over PCB 514 and gasket 620, which can be a very high bond (VHB) tape, ensures that there is no urethane leak during potting. During injection through one of holes 926 and 924, the tip of the static mixer sits against an off the shelf O-ring to ensure once again a leak free operation since urethane can be very messy, creates a quality control issue, and may increase the cost and weight of PSA 100. The other of holes 926 and 924 allow the air to exhaust as urethane is filling the volume of cover 622. Although two holes, holes 926 and 924, are shown in FIG. 9B, there may be any number of holes to facilitate the potting process. For example, in some embodiments holes 926 and 924 may include one fill hole through which the urethane is inserted and two vent holes through which air is vented. Once the urethane has cured, holes 926 and 924 are cut-off. Typically, urethane takes at least two hours to cure.

FIGS. 9C and 9D illustrate bonding and potting of solar cell 124 on the opposite side of heat sink 510 from PCB 514. This process can be accomplished in parallel with the mounting and potting of PCB 514 described with FIGS. 9A and 9B.

As shown in FIG. 9C, multiple drops 930 of urethane are positioned onto the surface of heat sink 510 and are allowed to cure for a set period of time. For example, for Z-6644 urethane, a cure time of two hours is possible. With a different urethane the time could be very different). This bonding can be done in parallel with the potting of the electronics as shown in FIGS. 9A and 9B. In some examples, 16 drops 930 of urethane can be positioned on heat sink 510. Curing can be accomplished in a curing chamber.

While drops 930 are curing, a Solar Cell 124 can be positioned in a bonding station. After 2 hours heatsink 510 is removed from the curing chamber and drops 930 are soft enough to still be deformed, sticky enough to still bond to solar cell 124 and stiff enough to push solar cell flat 124 against the bottom surface of the bonding station. This combination insures that solar cell 124 becomes flat after tabbing wires 312 and 314 have been soldered to it. A flat solar cell 124 with an even gap between solar cell 124 and heatsink 510 to facilitates a successful encapsulation. The clamps on the bonding station ensure that heatsink 510 is as flat as possible.

When heatsink 510 is clamped on the bonding station, the urethane drops 930 are compressed and deformed to create, after cure, a great way to firmly hold solar cell 124 in place until encapsulated. Also, since urethane sticks very well to urethane these urethane drops 930 get immersed by fresh urethane during encapsulation to form an homogeneous layer of bubble free urethane under solar cell 124. This process is shown in FIG. 9D. As shown in FIG. 9D, a urethane film 932 is applied over solar cell 124.

Currently the nominal gap between solar cell 124 and heatsink 510 can be as low as 0.3 mm. The gap between solar cell 124 and heatsink 510 should be as low as possible in order to maximize heat transfer and keep solar cell 124 as cool as possible. As discussed above, solar cells reduce their power performance as temperature increases. For mono-crystalline cells, for example, the reduction in performance is about 0.41±0.05%/° C. above 25° C. After encapsulation, cover 214 can be installed over heatsink 510 to form cell assembly 610, which is affixed to base 212 by screws.

In some embodiments, the system is waterproof. In some embodiments, the system is waterproof to a depth of at least one meter. In some embodiments, the electronics, substrate, and solar cell are encapsulated and potted simultaneously. In some embodiments, PSA 100 has positive buoyancy in water or seawater.

Embodiments described here are exemplary of the invention only and are not to be considered limiting. One skilled in the art will recognize numerous variations on the embodiments described here. Those variations should be considered to be included in the scope of this disclosure. As such, the invention is limited only by the following claims.

What is claimed is:

1. An apparatus, comprising:
a base with ventilation holes;
a heat sink coupled to the base;
at least one solar cell mounted to the heat sink opposite the base;
a printed circuit board mounted to the heat sink opposite the solar cell; and
a battery mounted to the base.

2. The apparatus of claim 1, wherein the base includes supports that provide mechanical support for the heat sink.

3. The apparatus of claim 2, wherein at least a portion of the supports facilitate air flow through the base.

4. The apparatus of claim 1, further including legs mounted to the base.

5. The apparatus of claim 4, wherein the legs are mounted utilizing a plastic detent.

6. The apparatus of claim 4, wherein the legs are mounted utilizing metal spring materials.

7. The apparatus of claim 1, further including a cover over the heat sink.

8. The apparatus of claim 7, wherein the cover includes top ventilation to help cool the solar cell.

9. The apparatus of claim 1, wherein the at least one solar cell is encapsulated to the heat sink.

10. The apparatus of claim 9, wherein the thickness of the encapsulation is determined by the Young's modulus (E) and Poisson ratio of the encapsulation material.

11. The apparatus of claim 1, wherein the electronics is potted to the heat sink.

12. The apparatus of claim 1, wherein the apparatus is waterproof.

13. The apparatus of claim 1, further including at least one connector mounted in the base.

14. The apparatus of claim 1, wherein the apparatus is structurally strong, resists damage due to rough handling, and self heals scratches to the solar cell encapsulant.

15. The apparatus of claim 1, further including reflectors coupled to concentrate additional sunlight onto the solar cell.

16. The apparatus of claim 15, wherein the reflectors may be added or removed.

17. The apparatus according to claim 15, wherein the reflectors possess an optimal geometry with respect to the solar cell.

18. The apparatus of claim 17, wherein the reflectors are twice as long as the solar cell.

19. The apparatus of claim 17, wherein the reflectors are mounted at an angle of 60 degrees from the plane of the solar cell.

20. The apparatus of claim 17 wherein the reflectors are centered on the plane of the solar cell.

21. The apparatus of claim 17, wherein the one or more solar cells are oriented perpendicular to the reflectors.

22. The apparatus of claim 15 where the reflectors are heat sinks for thermal load dissipation.

23. The apparatus of claim 1, further including one or more holes formed through the heat sink and the base for the purpose of securing the system to an external structure.

24. The apparatus of claim 1, wherein one or more of the printed circuit board, the reflectors, and the legs are user replaceable.

25. The apparatus of claim 1, wherein the system has positive buoyancy in water or seawater.

26. A method of forming a personal solar appliance, comprising:
affixing a printed circuit board to a bottom of a heat sink;
affixing a solar cell to a top of the heat sink;
attaching the heat sink to a ventilated base; and
attaching a battery to the base opposite the heat sink.

27. The method of claim 26, wherein affixing the printed circuit board includes
attaching the printed circuit board;
attaching a cover over the printed circuit board;
inserting potting material into the cover to pot electronics on the printed circuit board; and
curing the potting material.

28. The method of claim 26, wherein affixing the solar cell includes
placing a pattern of drops of urethane on the top of the heat sink;
curing the pattern of drops;
affixing the solar cell over the pattern of drops;
applying pressure to push the solar cell flat on the heat sink;
covering the solar cell with urethane; and
curing the urethane to encapsulate the solar cell.

29. The method of claim 26, wherein affixing the electronics and affixing the solar cell are performed, at least in part, in parallel.
